(19) United States
(12) Patent Application Publication
(10) Pub. No.: US 2008/0255283 A1
(43) Pub. Date: Oct. 16, 2008

(54) THERMOSETTING EPOXY RESIN COMPOSITION AND SEMICONDUCTOR DEVICE

(76) Inventors: Takayuki Aoki, Annaka-shi (JP); Tadaharu Ikeda, Annaka-shi (JP)

Correspondence Address: BIRCH STEWART KOLASCH & BIRCH, PO BOX 747, FALLS CHURCH, VA, 22040-0747, US

(21) Appl. No.: 12/026,433

(22) Filed: Feb. 5, 2008

(30) Foreign Application Priority Data
Feb. 6, 2007 (JP) 2007-026508
Feb. 6, 2007 (JP) 2007-026659

(51) Int. Cl. C08K 3/36; C08K 5/05; H01L 23/29; C08K 5/06

(52) U.S. Cl. 524/300; 524/606; 524/379; 257/793

(57) ABSTRACT

A thermosetting epoxy resin composition is provided comprising (A) a reaction product obtained through reaction of a triazine derived epoxy resin with an acid anhydride, (C) a reflective agent, (D) an inorganic filler, and (E) a curing catalyst. In one embodiment, (B) an internal parting agent having a melting point of 50-90° C. is included. In another embodiment, (I) inorganic whisker fibers having an average fineness of 0.05-50 μm and an average length of 1.0-1,000 μm are included.

### CROSS-REFERENCE TO RELATED APPLICATION

This non-provisional application claims priority under 35 U.S.C. §119(a) on Patent Application Nos. 2007-026659 and 2007-026508 filed in Japan on Feb. 6, 2007 and Feb. 6, 2007, respectively, the entire contents of which are hereby incorporated by reference.

### TECHNICAL FIELD

This invention relates to thermosetting epoxy resin compositions which effectively cure into products having improved heat resistance, light resistance, resistance to thermal discoloration, especially yellowing, and reliability; and semiconductor devices wherein light-receiving members and other semiconductor members (exclusive of light-emitting members like LED's, but inclusive of photocouplers having light-emitting and receiving members combined) are encapsulated with the cured compositions.

### BACKGROUND ART

The reliability demand on encapsulants for semiconductor and electronic devices becomes more stringent as the devices are reduced in size and profile and increased in output. For example, semiconductor members such as light-emitting diodes (LED) and laser diodes (LD) have many advantages including small size, efficiency, vivid color emission, elimination of bulb failure, excellent drive characteristics, resistance to vibration, and resistance to repeated turn-on and off. These semiconductor members are often utilized as various indicators and light sources.

At the present, polyphthalamide (PPA) resins are widely used as one class of encapsulating material for semiconductor and electronic devices using such semiconductor members, for example, photocouplers.

The current rapid advance of the photo-semiconductor technology has brought about photo-semiconductor devices of increased output and shorter wavelength. Photo-semiconductor devices such as photocouplers capable of transmitting or receiving high-energy light are often encapsulated or encased using prior art PPA resins as colorless or white material. However, these encapsulants and casings are substantially degraded during long-term service and susceptible to visible color variations, separation and a lowering of mechanical strength. It is desired to overcome these problems effectively.

More particularly, Japanese Patent No. 2,656,336 discloses that a photo-semiconductor device is encapsulated with a B-staged epoxy resin composition, in the cured state, comprising an epoxy resin, a curing agent, and a cure promoter, the components being uniformly mixed on a molecular level. As to the epoxy resin, it is described that bisphenol A epoxy resins or bisphenol F epoxy resins are mainly used although triglycidyl isocyanate and the like may also be used. In examples, triglycidyl isocyanate is added in a minor amount to the bisphenol epoxy resin. The present inventors have empirically found that this B-staged epoxy resin composition for semiconductor encapsulation tends to yellow when held at high temperatures for a long period of time.

Triazine derived epoxy resins are used in light-emitting member-encapsulating epoxy resin compositions as disclosed in JP-A 2000-196151, JP-A 2003-224305, and JP-A 2005-306952. None of these patents refer to the B-staged reaction product of a triazine derived epoxy resin with an acid anhydride.

JP-A 9-310007 discloses a liquid epoxy resin composition for electronic part encapsulation comprising an epoxy resin, a curing agent, and an inorganic filler wherein the inorganic filler contains 5 to 50% by weight of an acicular filler having an aspect ratio of at least 5. A seal coating of this composition has a sufficient flexural strength even when it is thin.

Furthermore, JP-A 2001-316591 discloses a dielectric composition comprising a thermosetting resin based on an epoxy resin and an epoxy resin curing agent, dielectric whiskers, and a silicone powder. The composition has flame retardance, effective infiltration into inner layer circuits, heat resistance, and reliability. Using the composition, dielectric-covered metal foils and metal-clad laminates are manufactured.

While the foregoing patents generally refer to an improvement in strength, they have certain restrictions. For example, some are restricted to liquid epoxy resin compositions, and some are applicable to only laminates. Under the current circumstance where photo-semiconductor devices such as photocouplers capable of transmitting or receiving high-energy light make rapid advances toward greater outputs and shorter wavelengths, the outstanding problem is that sufficient strength and impact resistance are unobtainable unless a specific epoxy resin having a basic formulation featuring heat resistance and light resistance is combined with a curing agent.

Reference should also be made to Japanese Patent No. 3,512,732, JP-A 2001-234032, JP-A 2002-302533, and Electronics Packaging Technology, April 2004.

### DISCLOSURE OF THE INVENTION

An object of the invention is to provide thermosetting epoxy resin compositions which cure into uniform products capable of maintaining white color, heat resistance and light resistance over a long period of time without substantial yellowing and which are effectively moldable and improved in mold release.

Another object of the invention is to provide thermosetting epoxy resin compositions which are molded and cured into uniform products having improved strength, toughness and thermal shock resistance and maintaining white color, heat resistance and light resistance without substantial yellowing.

A further object of the invention is to provide semiconductor devices wherein semiconductor members (exclusive of light emitting members like LED's, but inclusive of photocouplers having light-emitting and receiving members combined) are encapsulated with the cured compositions.

The inventors have found that a thermosetting epoxy resin composition comprising (A) a reaction product obtained through reaction of a triazine derived epoxy resin with an acid anhydride in an epoxy group equivalent to acid anhydride group equivalent ratio from 0.6 to 2.0, (B) an internal parting agent, (C) a reflective agent, (D) an inorganic filler, and (E) a curing catalyst as essential components becomes continuously moldable, effectively releasable from the mold, and curable into products with heat resistance and light resistance when the internal parting agent (B) comprises a component having the general formula (1), defined below, and a melting point in the range of 50° C. to 90° C.

The inventors have also found that a thermosetting epoxy resin composition comprising (A) a reaction product obtained through reaction of a triazine derived epoxy resin with an acid anhydride in an epoxy group equivalent to acid anhydride group equivalent ratio from 0.6 to 2.0, (I) inorganic whisker fibers, (C) a reflective agent, (D) an inorganic filler, and (E) a curing catalyst as essential components becomes moldable and curable into products having a satisfactory strength, toughness, heat resistance and light resistance when the whisker fibers (I) have an average fineness of 0.05 to 50 μm and an average length of 1.0 to 1,000 μm and are present in an amount of 0.001 to 30% by weight based on the total weight of the composition, and preferably the composition further comprises (J) a silicone powder.

In a first aspect, the invention provides a thermosetting epoxy resin composition comprising

(A) a reaction product obtained through reaction of a triazine derived epoxy resin with an acid anhydride in an epoxy group equivalent to acid anhydride group equivalent ratio from 0.6 to 2.0,

(B) an internal parting agent,

(C) a reflective agent,

(D) an inorganic filler, and

(E) a curing catalyst,

the internal parting agent (B) comprising a component having the general formula (1) and a melting point in the range of 50° C. to 90° C.,

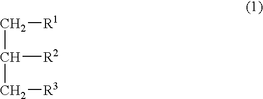

wherein R¹, R², and R³ are each independently H, —OH, —OR or —OCOCₐH_{b}, at least one of R¹, R², and R³ including —OCOCₐH_{b}, R is an alkyl group: CₙH₂ₙ₊₁ wherein n is an integer of 1 to 30, “a” is an integer of 10 to 30, and “b” is an integer of 17 to 61.

In a preferred embodiment, the composition may further comprise (F) an antioxidant. In a preferred embodiment, the internal parting agent (B) comprises glycerol monostearate having a melting point of 50 to 70° C. and is present in an amount of 0.2 to 5.0% by weight based on the total weight of the composition; or the internal parting agent (B) comprises a propylene glycol fatty acid ester and is present in an amount of 0.2 to 5.0% by weight based on the total weight of the composition.

In a second aspect, the invention provides a thermosetting epoxy resin composition comprising

(A) a reaction product obtained through reaction of a triazine derived epoxy resin with an acid anhydride in an epoxy group equivalent to acid anhydride group equivalent ratio from 0.6 to 2.0,

(I) inorganic whisker fibers,

(C) a reflective agent,

(D) an inorganic filler, and

(E) a curing catalyst,

the whisker fibers (I) having an average fineness of 0.05 to 50 μm and an average length of 1.0 to 1,000 μm and being present in an amount of 0.001 to 30% by weight based on the total weight of the composition.

In a preferred embodiment, the composition may further comprise (J) a silicone powder. Specifically the silicone powder (J) is a powder of spherical silicone rubber particles surface coated with an epoxy resin. In a preferred embodiment, the composition may further comprise (F) an antioxidant.

In preferred embodiments of the first and second aspects, the triazine derived epoxy resin in component (A) is a 1,3,5-triazine nucleus derived epoxy resin. More preferably, the reaction product (A) comprises a compound having the general formula (2):

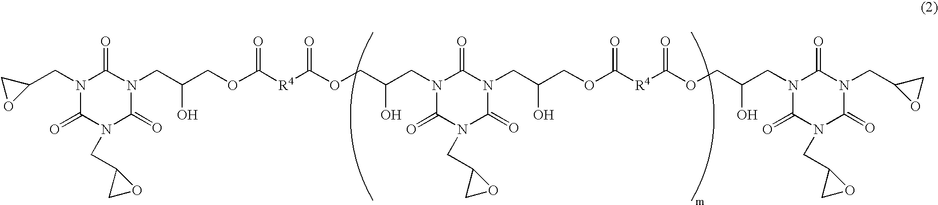

wherein R⁴ is an acid anhydride residue and m is a number from 0 to 200.

The compositions are used to form a casing for semiconductor members excluding light-emitting members.

Also contemplated herein is a semiconductor device comprising a semiconductor member (exclusive of light-emitting members, but inclusive of integral members having a light-emitting member combined with a light-receiving member), which is encapsulated with the epoxy resin composition of the first or second aspect in the cured state.

### BENEFITS OF THE INVENTION

The thermosetting epoxy resin compositions of the first embodiment have the desirable property of ready adaptation to molding and mold release, and can be cured into uniform products with heat resistance, light resistance and minimal yellowing. The thermosetting epoxy resin compositions of the second embodiment can be molded and cured into uniform products having a satisfactory strength, toughness, especially thermal shock resistance, and maintaining heat resistance and light resistance over a long period of time without substantial yellowing. Then semiconductor and electronic devices such as photocouplers which are encapsulated with the cured compositions are of great worth in the industry.

### BRIEF DESCRIPTION OF THE DRAWING

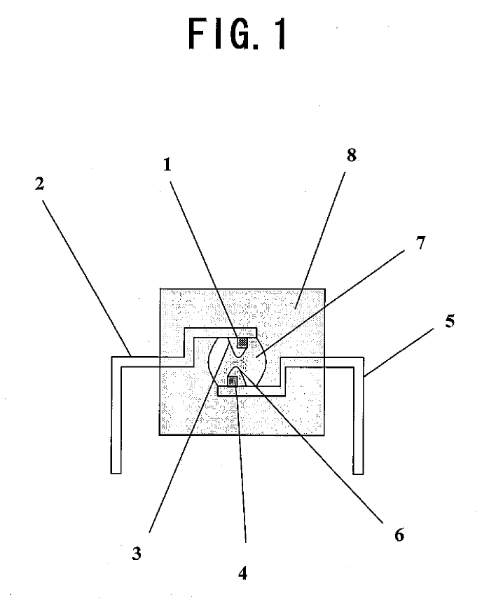

The only FIGURE, FIG. 1 is a cross-sectional view of an exemplary photocoupler encapsulated with a thermosetting epoxy resin composition of the invention.

### DESCRIPTION OF THE PREFERRED EMBODIMENTS

### First Embodiment

The thermosetting epoxy resin composition according to the first embodiment of the invention is described below.

### A. Reaction Product

The thermosetting epoxy resin composition according to the first embodiment of the invention uses as a resin component a reaction product which is obtained by mixing (A-1) a triazine derived epoxy resin with (A-2) an acid anhydride in a ratio of epoxy group equivalent to acid anhydride group equivalent of 0.6:1 to 2.0:1, and reacting them.

(A-1) Triazine Derived Epoxy Resin

The triazine derived epoxy resin (A-1) used herein is such that when a reaction product obtained through reaction thereof with an acid anhydride in a specific proportion is formulated as a resin component, the resulting thermosetting epoxy resin composition undergoes little yellowing and is thus suitable for encapsulation to fabricate a semiconductor device which is subject to little degradation with time. The preferred triazine derived epoxy resins include 1,3,5-triazine nucleus derived epoxy resins. Epoxy resins having isocyanurate rings have better light resistance and electrical insulation, with those having two, and more preferably three epoxy groups per isocyanurate ring being desirable. Useful examples include tris(2,3-epoxypropyl)isocyanurate, tris(α-methylglycidyl)isocyanurate, and tris(α-methylglycidyl)isocyanurate.

The triazine derived epoxy resins used herein preferably have a softening point of 90 to 125° C. It is noted that the triazine derived epoxy resins used herein exclude hydrogenated triazine rings.

(A-2) Acid Anhydride

The acid anhydride (A-2) used herein serves as a curing agent. For light resistance, acid anhydrides which are non-aromatic and free of a carbon-carbon double bond are preferred. Examples include hexahydrophthalic anhydride, methylhexahydrophthalic anhydride, trialkyltetrahydrophthalic anhydrides, and hydrogenated methylnadic anhydride, with methylhexahydrophthalic anhydride being most preferred. These acid anhydride curing agents may be used alone or in admixture.

The acid anhydride curing agent is used in such amounts that 0.6 to 2.0 equivalents, preferably 1.0 to 2.0 equivalents, more preferably 1.2 to 1.6 equivalents of epoxy groups in the triazine derived epoxy resin (A) are available per equivalent of acid anhydride groups. If the ratio of epoxy group equivalent to acid anhydride group equivalent is less than 0.6, there may occur under-cure and a loss of reliability. If the ratio is more than 2.0, the unreacted curing agent may be left in the cured composition, detracting from the moisture resistance thereof.

In the practice of the invention, components (A-1) and (A-2), preferably components (A-1), (A-2) and an antioxidant, to be described later, are previously heated for reaction at a temperature of 70 to 120° C., preferably 80 to 110° C., for 4 to 20 hours, preferably 6 to 15 hours, or components (A-1), (A-2) and a curing catalyst, to be described later, preferably components (A-1), (A-2), an antioxidant and a curing catalyst, to be described later, are previously heated for reaction at a temperature of 30 to 80° C., preferably 40 to 60° C., for 10 to 72 hours, preferably 36 to 60 hours, forming a solid reaction product having a softening point of 50 to 100° C., preferably 60 to 90° C. The solid reaction product is then ground before formulating. A reaction product having a softening point of less than 50° C. does not become solid whereas a reaction product having a softening point of higher than 100° C. may lose fluidity. Too short a reaction time may yield a reaction product which does not become solid due to less contents of high molecular weight fractions whereas too long a reaction time may detract from fluidity. It is noted that the “softening point” as used herein is measured by the ring and ball method of the JIS standard.

The (solid) reaction product obtained herein, that is, the reaction product of triazine derived epoxy resin (A-1) and acid anhydride (A-2) is preferably such that when the reaction product is analyzed by gel permeation chromatography (GPC) under conditions including a sample concentration 0.2 wt %, a feed volume 50 μl, a mobile phase THF 100%, a flow rate 1.0 ml/min, a temperature 40° C., and a detector RI, it contains 20 to 70% by weight of a high molecular weight fraction with a weight average molecular weight of more than 1,500, 10 to 60% by weight of a moderate molecular weight fraction with a weight average molecular weight of 300-1,500, and 10 to 40% by weight of a monomeric fraction.

The reaction product contains a reaction product having the formula (2) when component (A-1) used is triglycidyl isocyanate, and more specifically, a reaction product having the formula (3) when component (A-1) used is triglycidyl isocyanate and component (A-2) used is methylhexahydrophthalic anhydride.

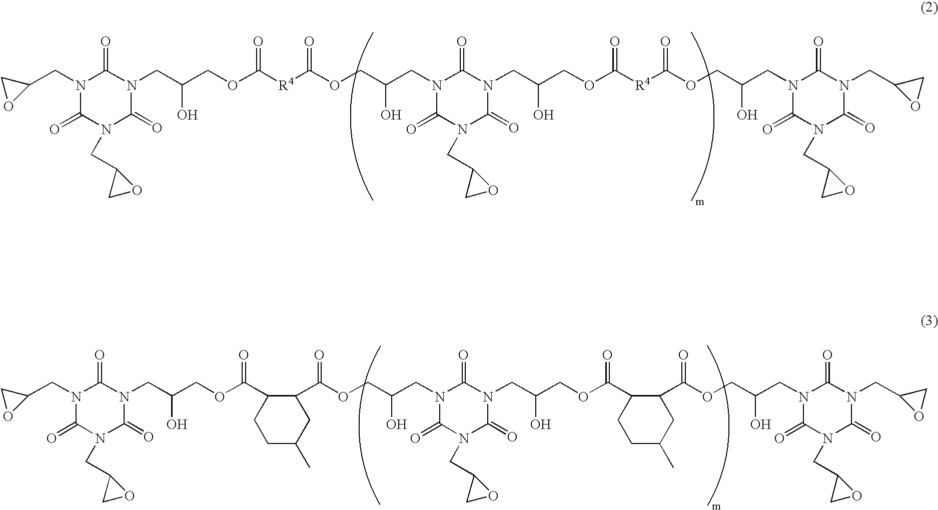

Herein, R⁴ is an acid anhydride residue and m is a number of 0 to 200 and preferably 0 to 100. These reaction products have an average molecular weight of 500 to 100,000.

As previously described, the reaction product preferably contains 20 to 70%, especially 30 to 60% by weight of a high molecular weight fraction with a molecular weight of more than 1,500, 10 to 60%, especially 10 to 40% by weight of a moderate molecular weight fraction with a molecular weight of 300-1,500, and 10 to 40%, especially 15 to 30% by weight of a monomeric fraction (unreacted epoxy resin and acid anhydride).

In addition to the reaction product (A), the thermosetting epoxy resin composition of the first embodiment comprises (B) an internal parting agent, (C) a reflective agent, (D) an inorganic filler, and (E) a curing catalyst as essential components. In a preferred embodiment, there may be further compounded (F) an antioxidant and optionally (G) another epoxy resin.

### B. Internal Parting Agent

In the epoxy resin composition, (B) an internal parting agent is compounded for facilitating mold release of the composition upon molding. The internal parting agent (B) comprises a compound having the general formula (1) and a melting point in the range of 50° C. to 90° C.

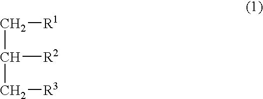

Herein R¹, R², and R³ are each independently H, —OH, —OR or —OCOCₐH_{b}, at least one of R¹, R², and R³ includes —OCOCₐH_{b}, R is an alkyl group: CₙH₂ₙ₊₁ wherein n is an integer of 1 to 30, “a” is an integer of 10 to 30, and “b” is an integer of 17 to 61.

The internal parting agent (B) may be added in an amount of 0.2 to 5.0% by weight based on the total weight of the composition.

Known internal parting agents include natural waxes such as carnauba wax, and synthetic waxes such as acid waxes, polyethylene waxes, and fatty acid waxes. When exposed to high temperatures or light, most parting agents are prone to yellowing and are degraded with time, eventually losing parting properties. Among these, the internal parting agents having formula (1) are unsusceptible to yellowing when exposed to high temperatures or light, and maintain satisfactory-parting properties over a long period of time.

In formula (1), at least one of R¹, R², and R³ should be —OCOCₐH_{b}. Although the compound of formula (1) wherein all R¹, R², and R³ are —OH fails to provide the composition with parting properties and heat resistance, compounds having —OCOCₐH_{b} incorporated in their structure provide for good compatibility, heat resistance and parting properties.

In the formula: —OCOCₐH_{b}, “a” is an integer of 10 to 30, and preferably 11 to 20. If “a” is less than 10, then thermal yellowing resistance may be insufficient. If “a” is more than 30, the compound may fail to provide for compatibility and parting effect. The moiety CₐH_{b} may be a saturated or unsaturated aliphatic hydrocarbon moiety. In the case of unsaturation, inclusion of one or two unsaturated groups is preferred. Preference is then given to b=2a+1, 2a−1 and 2a−3, and especially b=2a+1 and 2a−1. This suggests that “b” is an integer of 17 to 61 and preferably 19 to 41. More preferably, “b” is an integer of 21 to 61 and especially 23 to 41.

Examples of suitable internal parting agents include glycerol monopalmitate, glycerol monostearate, glycerol mono(12-hydroxystearate), glycerol tri(12-hydroxystearate), glycerol monobehenate, propylene glycol monopalmitate, propylene glycol monostearate, and propylene glycol monobehenate.

In order for these compounds to have heat resistant properties, their melting point and volatile matter at high temperatures are also significant. In this regard, a melting point of 50 to 90° C., and preferably 65 to 85° C. is recommended. The volatile content at 250° C. should preferably be up to 10% by weight. If the melting point is less than 50° C., satisfactory thermal yellowing resistance may not be obtained. If the melting point is above 90° C., the compound may fail to provide for compatibility and parting effect. From the aspects of dispersion and compatibility, glycerol monostearate having a melting point of 50 to 70° C. is especially preferred. Similarly, propylene glycol fatty acid esters are preferred.

It is noted that the parting agent of formula (1) should preferably account for 20 to 100%, and more preferably 50 to 100% by weight of the entire internal parting agent (B). The remainder of the parting agent may include natural waxes, acid waxes and other synthetic waxes as described above.

The internal parting agent (B) is preferably added in an amount of 0.2 to 5.0% by weight, and more preferably 0.5 to 3.0% by weight based on the total weight of the composition. An addition amount of less than 0.2 wt % may fail to provide for parting properties whereas an amount of more than 5.0 wt % may cause such defectives as bleeding and poor adhesion.

### C. Reflective Agent

In the epoxy resin composition, (C) a reflective agent is compounded. It serves as a white colorant for enhancing whiteness. The preferred reflective agent is titanium dioxide. Titanium dioxide has a unit lattice which may be rutile, anatase or brookite type. It is not limited in average particle size and shape although the average particle size is generally in a range of 0.05 to 5.0 μm. The titanium dioxide may be previously surface treated with hydrous oxides of aluminum, silicon or the like for enhancing its compatibility with and dispersibility in resins and inorganic fillers. While titanium dioxide is the preferred reflective agent or white colorant, potassium titanate, zirconium oxide, zinc sulfide, zinc oxide, magnesium oxide or the like may also be used alone or in combination with titanium dioxide as the reflective agent.

An amount of the reflective agent loaded is preferably 2 to 80% by weight and more preferably 5 to 50% by weight of the entire composition. Less than 2% by weight may fail to achieve a sufficient whiteness whereas more than 80% by weight may adversely affect molding operation, leaving unfilled or void defects.

### D. Inorganic Filler

In the epoxy resin composition, (D) an inorganic filler is compounded. For the inorganic filler (D), any of fillers which are commonly compounded in epoxy resin compositions may be used. Examples include silicas such as fused silica and crystalline silica, alumina, silicon nitride, aluminum nitride, boron nitride, glass fibers, and antimony trioxide although the reflective agent or white colorant described above as component (C) should be excluded.

These inorganic fillers are not particularly limited in average particle size and shape. They generally have an average particle size of 5 to 40 μm. It is noted that the average particle size can be determined as the weight average value D₅D or median diameter in particle size distribution measurement by the laser light diffraction technique.

The inorganic filler which has been surface treated with coupling agents such as silane coupling agents and titanate coupling agents may be compounded for enhancing the bond strength between the resin and the inorganic filler. Suitable and preferable coupling agents include, for example, epoxy functional alkoxysilanes such as γ-glycidoxypropyltrimethoxysilane, γ-glycidoxypropylmethyldiethoxysilane, and β-(3,4-epoxycyclohexyl)ethyltrimethoxysilane, amino functional alkoxysilanes such as N-β-(aminoethyl)-γ-aminopropyltrimethoxysilane, γ-aminopropyltriethoxysilane, and N-phenyl-γ-aminopropyltrimethoxysilane, and mercapto functional alkoxysilanes such as γ-mercaptopropyltrimethoxysilane. It is understood that the amount of the coupling agent used for surface treatment and the surface treatment technique are not particularly limited.

An amount of the inorganic filler loaded is preferably 20 to 700 parts by weight and more preferably 50 to 400 parts by weight per 100 parts by weight of the epoxy resin (A-1) and the acid anhydride (A-2) combined. Less than 20 pbw may fail to achieve a sufficient strength whereas more than 700 pbw may result in unfilled defects due to a viscosity buildup and failures such as separation within the device or package due to a loss of flexibility. The inorganic filler is preferably contained in an amount of 10 to 90% by weight and more preferably 20 to 80% by weight based on the entire composition.

### E. Curing Catalyst

The curing catalyst (E) used herein may be any of well-known curing catalysts which are commonly used in epoxy resin compositions of this type. Suitable catalysts include, but are not limited to, tertiary amines, imidazoles, organic carboxylic acid salts of amines and imidazoles, metal salts of organic carboxylic acids, metal-organic compound chelates, aromatic sulfonium salts, phosphorus-based catalysts such as organic phosphine compounds and phosphonium compounds, and salts of the foregoing, which may be used alone or in admixture. Of these, the imidazoles and phosphorus-based catalysts are preferred. More preferred are 2-ethyl-4-methylimidazole, methyltributylphosphonium dimethylphosphate, and quaternary phosphonium bromides.

The curing catalyst is preferably used in an amount of 0.05 to 5%, more preferably 0.1 to 2% by weight based on the entire composition. Outside the range, the resulting epoxy resin composition may have an undesired profile of heat resistance and moisture resistance.

### F. Antioxidant

In the epoxy resin composition, (F) an antioxidant is compounded if necessary. The antioxidant (F) used herein is typically selected from among phenolic, phosphorus-based and sulfur-based antioxidants.

Examples of suitable phenolic antioxidants include 2,6-di-t-butyl-p-cresol, butylated hydroxyanisole, 2,6-di-t-butyl-p-ethylphenol, stearyl-β-(3,5-di-t-butyl-4-hydroxyphenyl)propionate, 2,2′-methylenebis(4-methyl-6-t-butylphenol), 4,4′-butylidene bis(3-methyl-6-t-butylphenol), 3,9-bis[1,1-dimethyl-2-{β-(3-t-butyl-4-hydroxy-5-methyl-phenyl)propionyloxy}ethyl]-2,4,8,10-tetraoxaspiro[5,5]-undecane, 1,1,3-tris(2-methyl-4-hydroxy-5-t-butylphenyl)butane, and 1,3,5-trimethyl-2,4,6-tris(3,5-di-t-butyl-4-hydroxybenzyl)-benzene. Inter alia, 2,6-di-t-butyl-p-cresol is preferred.

Examples of suitable phosphorus-based antioxidants include triphenyl phosphite, diphenylalkyl phosphites, phenyldialkyl phosphites, tri(nonylphenyl) phosphite, trilauryl phosphite, trioctadecyl phosphite, distearyl pentaerythritol diphosphite, tris(2,4-di-tert-butylphenyl) phosphite, diisodecyl pentaerythritol diphosphite, di(2,4-di-tert-butylphenyl) pentaerythritol diphosphite, tristearyl sorbitol triphosphite, and tetrakis(2,4-di-tert-butylphenyl)-4,4′-biphenyl diphosphonate. Inter alia, triphenyl phosphite is preferred.

Examples of suitable sulfur-based antioxidants include dilauryl 3,3′-thiodipropionate, dimyristyl 3,3′-thiodipropionate, and distearyl 3,3′-thiodipropionate.

These antioxidants may be used alone or in admixture. It is especially preferred to use a phosphorus-based antioxidant alone or in combination with a phenolic antioxidant. When a mixture of a phenolic antioxidant and a phosphorus-based antioxidant is used, the phenolic antioxidant and the phosphorus-based antioxidant are preferably mixed in a weight ratio from 0:100 to 70:30, more preferably from 0:100 to 50:50.

The antioxidant is preferably used in an amount of 0.01 to 10% by weight, more preferably 0.03 to 5% by weight based on the epoxy resin composition. Outside the range, less amounts of the antioxidant may provide epoxy resin compositions which are less heat resistant or susceptible to discoloration whereas too much amounts may interfere with the cure, inviting losses of curability and strength.

### G. Other Epoxy Resins

If necessary, epoxy resins other than component (A-1) may be used in a limited amount as long as the objects of the invention are not compromised. Specifically, the amount of other epoxy resin added is 0 to 40 parts by weight, and more specifically 5 to 20 parts by weight per 100 parts by weight of component (A-1). Suitable other epoxy resins include bisphenol A epoxy resins, bisphenol F epoxy resins, biphenol type epoxy resins such as 3,3′,5,5′-tetramethyl-4,4′-biphenol epoxy resins and 4,4′-biphenol epoxy resins, phenol novolac type epoxy resins, cresol novolac type epoxy resins, bisphenol A novolac type epoxy resins, naphthalene diol epoxy resins, trisphenylol methane epoxy resins, tetrakisphenylol ethane epoxy resins, and phenol dicyclopentadiene novolac type epoxy resins in which aromatic rings are hydrogenated. The other epoxy resins should preferably have a softening point of 70 to 100° C.

### Second Embodiment

The thermosetting epoxy resin composition of the second embodiment comprises (A) a reaction product obtained through reaction of a triazine derived epoxy resin with an acid anhydride, (I) inorganic whisker fibers, (C) a reflective agent, (D) an inorganic filler, and (E) a curing catalyst as essential components. In a preferred embodiment, the composition further comprises (J) a silicone powder and also (F) an antioxidant. If desired, (G) another epoxy resin may be compounded in the composition. Of these components, components (A), (C), (D), (E), (F), and (G), namely, reaction product, reflective agent, inorganic filler, curing catalyst, antioxidant, and other epoxy resin are the same as described in the first embodiment. Herein, only components (I) and (J) are described.

### I. Whiskers

In the epoxy resin composition of the second embodiment, (I) whiskers or inorganic whisker fibers are loaded. Inorganic whisker fibers are loaded in order to increase the strength and toughness of molded parts. Suitable inorganic fibers include amorphous fibers such as glass fibers, borosilicate glass and rock wool, polycrystalline fibers such as carbon fibers and alumina fibers, single crystal fibers such as potassium titanate, calcium silicate, silicate glass, and aluminum borate, as well as magnesium sulfate, silicon carbide, silicon nitride, and metal fibers. Fibers of any type are acceptable although single crystal fibers are advantageously used in achieving a high strength.

The inorganic whisker fibers generally have an average fineness (or average fiber diameter) of 0.05 to 100 μm, preferably 0.05 to 50 μm, and more preferably 0.1 to 20 μm, and an average length of 0.1 to 1,000 μm, preferably 1 to 500 μm, more preferably 2 to 250 μm, even more preferably 5 to 100 μm, and most preferably 10 to 30 μm. If the average fineness of whiskers is less than 0.05 μm, satisfactory strength and toughness are not achievable. Whiskers with an average fineness of more than 100 μm tend to have negative impact on the surface smoothness and to lose microscopic uniform dispersion. If the average length of whiskers is less than 0.1 μm, there is a tendency of decreasing stiffness. Whiskers with an average length of more than 1,000 μm may be difficultly dispersible with other components and adversely affect flow.

The inorganic whisker fibers have an aspect ratio, defined as average length/average fineness, which is generally in the range of 2-300/1, preferably 2-100/1, and more preferably 3-50/1. Whiskers with an aspect ratio of less than 2/1 may be not always sufficiently effective in improving the strength of the epoxy resin composition. Whiskers with an aspect ratio of more than 300/1 can be broken during compounding operation and the epoxy resin composition loaded therewith may have a varying strength.

It is noted that the “average fineness” and “average length” as used herein are measured under a microscope.

The inorganic whisker fibers are compounded in an amount of 0.001 to 30% by weight and preferably 0.01 to 20% by weight based on the entire composition. Less than 0.001 wt % of fibers may fail to achieve the desired strength and toughness whereas more than 30 wt % may have significant negative impact on the flow.

### J. Silicone Powder

In the epoxy resin composition of the second embodiment, (J) a silicone powder is preferably compounded. Inclusion of silicone powder assists the epoxy resin composition in mitigating expansion and shrinkage by external heat or stresses by external forces.

Examples of the silicone powder (J) include powdered silicone rubbers obtained through three-dimensional crosslinkage of linear organopolysiloxane as described in JP-A 63-77942, JP-A 03-93834, and JP-A 04-198324, and powdered silicone rubbers as described in U.S. Pat. No. 3,843,601, JP-A 62-270660, and JP-A 59-96122. Also useful are composite silicone powders of the structure in which particles of silicone rubber prepared by any of the foregoing methods are surface coated with a silicone resin which is a cured polyorganosilsesquioxane having a three-dimensional network structure represented by (R′SiO_{3/2})ₙ wherein R′ is a substituted or unsubstituted monovalent hydrocarbon group (see JP-A 07-196815). As the silicone powder (J), there may be used either a single silicone powder or a blend of two or more different silicone powders. Inter alia, the composite silicone powder of the structure in which particles of silicone rubber are surface coated with a silicone resin is preferred.

The silicone powder preferably has an average particle size of 0.01 to 50 μm and more preferably 0.05 to 30 μm. An average particle size of less than 0.01 μm may fail to achieve satisfactory toughness and low modulus whereas an average particle size of more than 50 μm may detract from strength. It is noted that the “average particle size” as used herein is measured by the laser light diffraction scattering method.

The silicone powder which can be used herein is commercially available under the trade name of Trefil E-500, E-600, E-601 and E-850 from Dow Corning Toray Co., Ltd. and KMP-600, KMP-601, KMP-602, and KMP-605 from Shin-Etsu Chemical Co., Ltd.

The silicone powder is compounded in an amount of 0.001 to 30% by weight and preferably 0.005 to 20% by weight based on the entire composition. Less than 0.001 wt % of silicone powder may be too small to achieve high toughness and low modulus whereas more than 30 wt % may detract from strength.

The following description is common to both the first and second embodiments of the invention.

Various other additives may be incorporated in the epoxy resin composition, if necessary. For example, thermoplastic resins, thermoplastic elastomers, organic synthetic rubbers, internal parting agents such as fatty acid esters and glyceric esters, halogen-trapping agents, and the like may be added for improving selected properties as long as the objects of the invention are not compromised.

### Preparation of Epoxy Resin Composition

The epoxy resin composition of the invention is prepared as a molding compound by previously combining components (A-1) and (A-2), preferably components (A-1), (A-2) and (F), and uniformly melt mixing them at a temperature of 70 to 120° C., preferably 80 to 110° C. in a reactor such as a solventless system equipped with a heater, or by previously combining components (A-1), (A-2) and (E), preferably components (A-1), (A-2), (E) and (F), and uniformly melt mixing them at a temperature of 30 to 80° C., preferably 40 to 60° C. in a reactor such as a solventless system equipped with a heater. In the course of heating, the reaction mixture builds up its viscosity. The course continues until the mixture has a softening point sufficient to handle at room temperature, specifically a softening point of 50 to 100° C., preferably 60 to 90° C. The reaction mixture is then cooled whereupon it becomes solid.

The temperature range at which components are mixed is from 70° C. to 120° C., preferably from 80° C. to 110° C. when components (A-1) and (A-2), preferably components (A-1), (A-2) and (F) are combined together. Temperatures below 70° C. are too low to produce a mixture which becomes solid at room temperature. Temperatures above 120° C. provide too high a reaction rate, making it difficult to stop the reaction at the desired degree of reaction. The temperature range at which components (A-1), (A-2) and (E) or components (A-1), (A-2), (E) and (F) are mixed is from 30° C. to 80° C., preferably from 40° C. to 60° C. while the problems associated with lower or higher temperatures are the same as described above.

The solid reaction product is then ground and if necessary, combined with components (B) or (I), (C), (D) as well as (E) and optional (F) if components (E) and (F) have not been used in the preparation of the solid reaction product, and component (J) in the second embodiment, and other additives in accordance with a predetermined recipe. This is intimately mixed on a mixer or the like, melt mixed on a hot roll mill, kneader or extruder, cooled for solidification again, and ground to a suitable size whereupon the ground material is ready for use as a molding compound of epoxy resin composition.

The epoxy resin composition thus obtained is advantageously used as encapsulants for semiconductor and electronic devices and equipment (exclusive of light emitting devices such as LED's, but inclusive of integral members having light-emitting and receiving members combined such as photocouplers), especially for photocouplers. FIG. 1 is a cross-sectional view of a photocoupler as an exemplary semiconductor member encapsulated with the composition of the invention. The photocoupler shown in FIG. 1 includes a semiconductor member 1 of compound semiconductor which is die-bonded to a lead frame 2 and wire-bonded to another lead frame (not shown) via a bonding wire 3. A light-receiving semiconductor member 4, which is opposed to the semiconductor member 1, is die-bonded to a lead frame 5 and wire-bonded to another lead frame (not shown) via a bonding wire 6. A transparent sealant resin 7 fills in between the semiconductor members 1 and 4. The sealant resin 7 enclosing the semiconductor members 1 and 4 is encapsulated with the thermoset epoxy resin composition 8 of the invention.

The method of encapsulating the thermosetting epoxy resin composition over a semiconductor member(s) is most often low-pressure transfer molding. The epoxy resin composition of the invention is desirably molded at a temperature of 150 to 185° C. for 30 to 180 seconds and post-cured at a temperature of 150 to 185° C. for 2 to 20 hours.

### EXAMPLE

Examples and Comparative Examples are given below for illustrating the invention although they should not be construed as limiting the invention.

The ingredients used herein are listed below.

### A-1. Epoxy Resin

Triazine derived epoxy resin: tris(2,3-epoxypropyl)isocyanate, TEPIC-S by Nissan Chemical Industries, Ltd., epoxy equivalent 100

### A-2. Acid Anhydride

Carbon-carbon double bond-free acid anhydride: methylhexahydrophthalic anhydride, Rikacid MH by New Japan Chemical Co., Ltd.

### B. Internal Parting Agent

B-1: glycerol monostearate, H-100 by Riken Vitamin Co., Ltd.
B-2: propylene glycol monobehenate, PB-100 by Riken Vitamin Co., Ltd.
B-3: glycerol tri(12-hydroxystearate), TG-12 by Riken Vitamin Co., Ltd.
B-4: polyethylene wax, PE-190 by Clariant Japan
B-5: oxidized polyethylene wax, H-22 by Clariant Japan
B-6: acid wax, stearic acid by Wako Pure Chemical Industries, Ltd.
B-7: montanic acid wax, LICOWAX S by Clariant Japan
B-8: ester wax, LICOWAX E by Clariant Japan
B-9: carnauba wax, Carnauba Wax NS-lP by Nikko Fine Co., Ltd.
B-10: Metallocene wax, P-65 by Clariant Japan

### C. Reflective Agent

Titanium dioxide of rutile type, R-45M by Sakai Chemical Industry Co., Ltd.

### D. Inorganic Filler

Ground fused silica by Tatsumori Co., Ltd.

### E. Curing Catalyst

E-1: Phosphorus-based curing catalyst: methyltributylphosphonium dimethylphosphate, PX-4 MP by Nippon Chemical Industrial Co., Ltd.
E-2: Imidazole catalyst: 2-ethyl-4-methylimidazole, 2E4MZ by Shikoku Chemicals Corp.
E-3: Phosphorus-based curing catalyst: quaternary phosphonium bromide, U-CAT 5003 by San-Apro, Ltd.

### F. Antioxidant

F-1: Phosphorus-based antioxidant: triphenyl phosphate by Wako Pure Chemical Industries, Ltd.
F-2: Phenolic antioxidant: 2,6-di-t-butyl-p-cresol, BHT by Wako Pure Chemical Industries, Ltd.

### G. Other Epoxy Resin

G-1: Hydrogenated bisphenol A epoxy resin, YL-7170 by Japan Epoxy Resin Co., Ltd., epoxy equivalent 1,200
G-2: Hydrogenated biphenyl epoxy resin, YL-7040 by Japan Epoxy Resin Co., Ltd., epoxy equivalent 220
G-3: Bisphenol A epoxy resin, E1004 by Japan Epoxy Resin Co., Ltd., epoxy equivalent 890

### H. Other Curing Agent

H-1: Carbon-carbon double bond-containing acid anhydride: tetrahydrophthalic anhydride, Rikacid TH by New Japan Chemical Co., Ltd.
H-2: Phenol novolac resin, TD-2131 by Dainippon Ink & Chemicals, Inc.

### I. Inorganic Whisker Fibers

I-1: Potassium titanate, Tismo D by Otsuka Chemical Co., Ltd., fineness 0.5 μm, length 15 μm, aspect ratio 30
I-2: Calcium Silicate, KH-30 by Kansai Matec Co., Ltd., fineness 15 μm, length 100 μm, aspect ratio 7
I-3: Silicate glass, REV-9 by NSG Vetorotex, fineness 13 μm, length 35 μm, aspect ratio 3
I-4: Aluminum borate, Alborex YS2B by Shikoku Chemicals Corp., fineness 1 μm, length 20 μm, aspect ratio 20

### J. Silicone Powder

J-1: Composite silicone powder coated with silicone resin, KMP-605 by Shin-Etsu Chemical Co., Ltd., average particle size 2 μm
J-2: Silicone powder, Trefil E-500 by Dow Corning Toray Co., Ltd., average particle size 3 μm

### Experiments 1 to 10

The internal parting agents used were measured for a melting point, outer appearance and thermal yellowing, with the results shown in Table 1.

The thermal yellowing resistance was examined by placing 10 g of each internal parting agent in an aluminum dish, holding the sample at 180° C. for 24 hours, and measuring the yellowness of the sample.

TABLE 1

| | | | Melting | | Yellowing |
|---|---|---|---|---|---|
| | | | point | | resistance |
| Experiment | Internal parting agent | | (° C.) | Appearance | @ 180° C./24 hr |
| 1 | B-1: glycerol | H-100 | 68 | White | Transparent |
| | monostearate | | | | |
| 2 | B-2: propylene glycol | PB-100 | 56 | White | Transparent |
| | monobehenate | | | | |
| 3 | B-3: glycerol tri(12- | TG-12 | 85 | White | Transparent |
| | hydroxystearate) | | | | |
| 4 | B-4: polyethylene wax | PE-190 | 135 | White | Transparent |
| 5 | B-5: oxidized | H-22 | 105 | White | Faintly |
| | polyethylene wax | | | | yellow |
| 6 | B-6: acid wax | Stearic | 70 | White | Faintly |
| | | acid | | | yellow |
| 7 | B-7: montanic acid wax | LICOWAX S | 84 | White | Yellow |
| 8 | B-8: ester wax | LICOWAX E | 82 | Faintly | Yellow |
| | | | | yellow | |
| 9 | B-9: carnauba wax | Carnauba Wax | 82 | Yellow | Brown |
| | | NS-1P | | | |
| 10 | B-10: Metallocene wax | P-65 | 105 | White | Brown |

### Examples 1-10 and Comparative Examples 1-8

Based on the thermal yellowing test results of Experiments shown in Table 1, Experiments 1 to 4 with better results and Experiments 5 and 6 with acceptable results were chosen.

White epoxy resin compositions for use with photocouplers were prepared according to the formulation shown in Tables 2 and 3, specifically by previously melt mixing an epoxy resin, an acid anhydride and an antioxidant in a reactor at 100° C. for 3 hours, cooling the reaction mixture for solidification (softening point 60° C.), grinding the reaction product, combining it with the remaining components, uniformly melt mixing on a hot two-roll mill, cooling and grinding.

These compositions were examined for the following properties, with the results shown in Tables 2 and 3.

Spiral Flow

Using a mold according to EMMI standards, a spiral flow was measured at 175° C. and 6.9 N/mm² for a molding time of 120 seconds.

Melt Viscosity

Using a constant-load orifice type flow tester with a nozzle having a diameter of 1 mm, a viscosity was measured at a temperature of 175° C. and a load of 10 kgf.

Flexural Strength

Using a mold according to EMMI standards, a specimen was molded at 175° C. and 6.9 N/mm² for 120 seconds. It was measured for flexural strength.

Continuous Molding

In a continuous molding machine, a mold of the package design of 100P-QFP (14×20×2.7 mm) having 6 cavities per frame was mounted. The mold was cleaned with a melamine resin, mold release recovery agent, after which molding cycles at 180° C. for 60 seconds were repeated. Molding operation was continued until it was interrupted by an obstructed release (by gate or runner breakage) or a short shot. The number of shots was counted, provided that the upper limit was 300 shots.

Heat Resistance or Yellowing

A disk having a diameter of 50 mm and a thickness of 3 mm was molded at 175° C. and 6.9 N/mm² for a molding time of 2 minutes and allowed to stand at 180° C. for 24 hours, after which a yellowness index was measured.

TABLE 2

| | | | | | | | | Comparative | | |
|---|---|---|---|---|---|---|---|---|---|---|
| | | Example | | | | | | Example | | |
| Formulation (pbw) | | 1 | 2 | 3 | 4 | 5 | 6 | 1 | 2 | 3 |
| (A-1) Epoxy | TEPIC-S | 9 | 9 | 9 | 9 | 9 | 9 | 9 | 9 | 9 |
| resin | | | | | | | | | | |
| (A-2) Acid | MH | 14 | 14 | 14 | 14 | 14 | 14 | 14 | 14 | 14 |
| anhydride | | | | | | | | | | |
| Reaction of (A-1) + (A-2) | | Yes | Yes | Yes | Yes | Yes | Yes | Yes | Yes | Yes |
| (B) Internal | B-1: H-100 | 1 | 2 | | | 1 | 1 | | | |
| parting | B-2: PB-100 | | | 2 | | 2 | | | | |
| agent | B-3: TG-12 | | | | 2 | | | | | |
| | B-4: PE-190 | | | | | | | 2 | | |
| | B-5: H-22 | | | | | | | | 2 | |
| | B-6: Stearic | | | | | | | | | 2 |
| | acid | | | | | | | | | |
| (C) Titanium | R-45M | 30 | 30 | 30 | 30 | 30 | 30 | 30 | 30 | 30 |
| dioxide | | | | | | | | | | |
| (D) Inorganic filler | | 46 | 45 | 45 | 44 | 44 | 46 | 47 | 44 | 44 |
| (E) Curing catalyst | UCAT5003 | 0.1 | 0.1 | 0.1 | 0.1 | 0.1 | 0.1 | 0.1 | 0.1 | 0.1 |
| (F) Antioxidant | Triphenyl | 0.1 | 0.1 | 0.1 | 0.1 | 0.1 | | 0.1 | 0.1 | 0.1 |
| | phosphite | | | | | | | | | |
| Test results | Spiral flow, | 18 | 19 | 18 | 20 | 20 | 18 | 15 | 17 | 17 |
| | inch | | | | | | | | | |
| | Melt viscosity, | 90 | 85 | 88 | 80 | 88 | 90 | 100 | 96 | 90 |
| | Pa-s | | | | | | | | | |
| | Flexural strength, | 90 | 88 | 90 | 85 | 86 | 90 | 90 | 90 | 90 |
| | N/mm² | | | | | | | | | |
| | Continuous | 300< | 300< | 300< | 300< | 300< | 300< | 3 | 40 | 35 |
| | molding, shots | | | | | | | | | |
| | Heat resistance | white | white | white | white | white | white | white | pale | yellow |
| | or Yellowing | | | | | | | | yellow | |

TABLE 3

| | | Example | | | | Comparative Example | | | | |
|---|---|---|---|---|---|---|---|---|---|---|
| Formulation (pbw) | | 7 | 8 | 9 | 10 | 4 | 5 | 6 | 7 | 8 |
| Epoxy | (A-1) | 9 | 8 | 4 | 6 | 9 | 2 | | | |
| resin | (G-1) | | 3 | 11 | | | 71 | 20 | | |
| | (G-2) | | | | 6 | | | | | |
| | (G-3) | | | | | | | | 20 | 21 |
| Curing | (A-2) | 14 | 12 | 8 | 12 | 14 | 5 | | 3 | |
| agent | (H-1) | | | | | | | 3 | | |
| | (H-2) | | | | | | | | | 2 |
| Antioxidant | (F-1) | 0.1 | 0.1 | 0.1 | 0.1 | 0.1 | | 0.1 | 0.1 | 0.1 |
| | (F-2) | 0.1 | 0.1 | 0.1 | 0.1 | | | 0.1 | 0.1 | 0.1 |
| Premixing or reaction of | | Yes | Yes | Yes | Yes | No | No | Yes | Yes | Yes |
| epoxy resin + curing | | | | | | | | | | |
| agent + antioxidant | | | | | | | | | | |
| Internal | (B-1) | 1 | 1 | 1 | 1 | 1 | 1 | 1 | 1 | 1 |
| parting | (B-2) | | | | | | | | | |
| agent | (B-3) | | | | | | | | | |
| | (B-4) | | | | | | | | | |
| | (B-5) | | | | | | | | | |
| | (B-6) | | | | | | | | | |
| Titanium | (C) | 6 | 6 | 6 | 6 | 6 | 6 | 6 | 6 | 6 |
| dioxide | | | | | | | | | | |
| Inorganic | (D) | 70 | 70 | 70 | 70 | 70 | 70 | 70 | 70 | 70 |
| filler | | | | | | | | | | |
| Curing | (E-1) | 0.1 | 0.1 | 0.1 | 0.1 | | 0.1 | 0.1 | 0.1 | 0.1 |
| catalyst | (E-2) | | | | | 0.1 | | | | |
| Test | Spiral flow, | 25 | 20 | 18 | 20 | 15 | 15 | 25 | 18 | 17 |
| results | inch | | | | | | | | | |
| | Melt viscosity, | 60 | 90 | 100 | 80 | 80 | 120 | 90 | 100 | 120 |
| | Pa-s | | | | | | | | | |
| | Flexural | 110 | 150 | 180 | 120 | 80 | 150 | 60 | 90 | 160 |
| | strength, N/mm² | | | | | | | | | |
| | Continuous | 300< | 300< | 300< | 300< | 300< | 300< | 300< | 300< | 300< |
| | molding, shots | | | | | | | | | |
| | Heat resistance | white | white | white | white | faintly | faintly | yellow | yellow | pale |
| | or Yellowing | | | | | yellow | yellow | | | yellow |

### Examples 11-33 and Comparative Examples 9-10

White epoxy resin compositions for use with photocouplers were prepared according to the formulation shown in Tables 4 and 5, specifically by previously melt mixing an epoxy resin, an acid anhydride and an antioxidant in a reactor at 100° C. for 3 hours, cooling the reaction mixture for solidification (softening point 60° C.), grinding the reaction product, combining it with the remaining components, uniformly melt mixing on a hot two-roll mill, cooling and grinding.

These compositions were examined for the following properties, with the results shown in Tables 4 and 5.

Spiral Flow

Using a mold according to EMMI standards, a spiral flow was measured at 175° C. and 6.9 N/mm² for a molding time of 120 seconds.

Melt Viscosity

Using a constant-load orifice type flow tester with a nozzle having a diameter of 1 mm, a viscosity was measured at a temperature of 175° C. and a load of 10 kgf.

Flexural Strength

Using a mold according to EMMI standards, a specimen was molded at 175° C. and 6.9 N/mm² for 120 seconds. Using a three-point bending tester, it was measured for flexural strength at room temperature.

Flexural Strength, Flexural Modulus, Deflection at 260° C.

Using a mold according to EMMI standards, a specimen was molded at 175° C. and 6.9 N/mm² for 120 seconds. It was held in a thermostat tank at 260° C. for 5 minutes, after which it was measured for strength, modulus and deflection (a travel distance of a load cell until breakage), using a three-point bending tester.

Heat Resistance or Yellowing

A disk having a diameter of 50 mm and a thickness of 3 mm was molded at 175° C. and 6.9 N/mm² for a molding time of 2 minutes and allowed to stand at 180° C. for 24 hours, after which a yellowness index was measured.

TABLE 4

| | | Example | | | | | | | | | | | | |
|---|---|---|---|---|---|---|---|---|---|---|---|---|---|---|
| Formulation (pbw) | | 11 | 12 | 13 | 14 | 15 | 16 | 17 | 18 | 19 | 20 | 21 | 22 | 23 |
| (A-1) Epoxy | TEPIC-S | 9 | 9 | 9 | 9 | 9 | 9 | 9 | 9 | 9 | 9 | 9 | 9 | 9 |
| resin | | | | | | | | | | | | | | |
| (A-2) Acid | Rikacid MH | 14 | 14 | 14 | 14 | 14 | 14 | 14 | 14 | 14 | 14 | 14 | 14 | 14 |
| anhydride | | | | | | | | | | | | | | |
| Reaction of (A-1) + (A-2) | | Yes | Yes | Yes | Yes | Yes | Yes | Yes | Yes | Yes | Yes | Yes | Yes | Yes |
| (I) Inorganic | (I-1) Tismo D | 5 | | | | 5 | | | | 5 | | | | 0.5 |
| whisker | (I-2) KH-30 | | 5 | | | | 5 | | | | 5 | | | |
| fibers | (I-3) REV-9 | | | 5 | | | | 5 | | | | 5 | | |
| | (I-4) YS2B | | | | 5 | | | | 5 | | | | 5 | |
| (C) Titanium | R-45M | 35 | 35 | 35 | 35 | 35 | 35 | 35 | 35 | 35 | 35 | 35 | 35 | 35 |
| dioxide | | | | | | | | | | | | | | |
| (D) Inorganic filler | | 35 | 35 | 35 | 35 | 30 | 30 | 30 | 30 | 30 | 30 | 30 | 30 | 39.5 |
| (E) Curing | (E-3) U-CAT5003 | 0.1 | 0.1 | 0.1 | 0.1 | 0.1 | 0.1 | 0.1 | 0.1 | 0.1 | 0.1 | 0.1 | 0.1 | 0.1 |
| catalyst | | | | | | | | | | | | | | |
| (J) Silicone | (J-1) KMP-605 | | | | | 5 | 5 | 5 | 5 | | | | | |
| powder | (J-2) Trefil | | | | | | | | | 5 | 5 | 5 | 5 | |
| | E-500 | | | | | | | | | | | | | |
| (F) Antioxidant | (F-1) Triphenyl | 0.1 | 0.1 | 0.1 | 0.1 | 0.1 | 0.1 | 0.1 | 0.1 | 0.1 | 0.1 | 0.1 | 0.1 | 0.1 |
| | phosphite | | | | | | | | | | | | | |
| Test | Spiral flow, | 26 | 24 | 23 | 25 | 19 | 23 | 22 | 24 | 19 | 18 | 17 | 20 | 25 |
| results | inch | | | | | | | | | | | | | |
| | Melt viscosity, | 86 | 78 | 90 | 82 | 97 | 85 | 92 | 87 | 97 | 91 | 93 | 86 | 85 |
| | Pa-s | | | | | | | | | | | | | |
| | Flexural strength | 86 | 82 | 85 | 83 | 84 | 85 | 88 | 84 | 84 | 83 | 86 | 83 | 84 |
| | at RT, N/mm² | | | | | | | | | | | | | |
| | Flexural strength | 6 | 5 | 6 | 5 | 8 | 8 | 9 | 7 | 8 | 7 | 7 | 7 | 5 |
| | at 260° C., N/mm² | | | | | | | | | | | | | |
| | Flexural modulus | 130 | 100 | 116 | 104 | 94 | 80 | 86 | 82 | 94 | 94 | 92 | 96 | 122 |
| | at 260° C., N/mm² | | | | | | | | | | | | | |
| | Deflection | 6 | 5 | 5 | 6 | 7 | 8 | 7.5 | 7 | 7 | 6 | 7 | 6 | 8 |
| | at 260° C., mm | | | | | | | | | | | | | |
| | Heat resistance | white | white | white | white | white | white | white | white | white | white | white | white | white |
| | or Yellowing | | | | | | | | | | | | | |

TABLE 5

| | | | | | | | | | | | | Comparative | |
|---|---|---|---|---|---|---|---|---|---|---|---|---|---|
| | | Example | | | | | | | | | | Example | |
| Formulation (pbw) | | 24 | 25 | 26 | 27 | 28 | 29 | 30 | 31 | 32 | 33 | 9 | 10 |
| (A-1) Epoxy | TEPIC-S | 9 | 9 | 9 | 9 | 9 | 9 | 9 | 9 | 9 | 9 | 9 | 9 |
| resin | | | | | | | | | | | | | |
| (A-2) Acid | Rikacid MH | 14 | 14 | 14 | 14 | 14 | 14 | 14 | 14 | 14 | 14 | 14 | 14 |
| anhydride | | | | | | | | | | | | | |
| Reaction of (A-1) + (A-2) | | Yes | Yes | Yes | Yes | Yes | Yes | Yes | Yes | Yes | Yes | Yes | Yes |
| (I) Inorganic | (I-1) Tismo D | 10 | 25 | 30 | 0.5 | 10 | 25 | 30 | 5 | 5 | 5 | | |
| whisker | (I-2) KH-30 | | | | | | | | | | | | |
| fibers | (I-3) REV-9 | | | | | | | | | | | | |
| | (I-4) YS2B | | | | | | | | | | | | |
| (C) Titanium | R-45M | 35 | 35 | 35 | 35 | 35 | 35 | 35 | 35 | 35 | 35 | 35 | 35 |
| dioxide | | | | | | | | | | | | | |
| (D) Inorganic filler | | 30 | 15 | 10 | 34.5 | 25 | 10 | 5 | 34.5 | 25 | 10 | 40 | 35 |
| (E) Curing | (E-3) U-CAT5003 | 0.1 | 0.1 | 0.1 | 0.1 | 0.1 | 0.1 | 0.1 | 0.1 | 0.1 | 0.1 | 0.1 | 0.1 |
| catalyst | | | | | | | | | | | | | |
| (J) Silicone | (J-1) KMP-605 | | | | 5 | 5 | 5 | 5 | 0.5 | 10 | 25 | | 5 |
| powder | (J-2) Trefil | | | | | | | | | | | | |
| | E-500 | | | | | | | | | | | | |
| (F) Antioxidant | (F-1) Triphenyl | 0.1 | 0.1 | 0.1 | 0.1 | 0.1 | 0.1 | 0.1 | 0.1 | 0.1 | 0.1 | 0.1 | 0.1 |
| | phosphite | | | | | | | | | | | | |
| Test | Spiral flow, | 27 | 26 | 27 | 28 | 23 | 21 | 19 | 26 | 23 | 21 | 30 | 24 |
| results | inch | | | | | | | | | | | | |
| | Melt viscosity, | 82 | 86 | 87 | 85 | 92 | 98 | 99 | 87 | 95 | 97 | 75 | 92 |
| | Pa-s | | | | | | | | | | | | |
| | Flexural strength | 88 | 89 | 90 | 88 | 94 | 97 | 99 | 93 | 88 | 87 | 55 | 31 |
| | at RT, N/mm² | | | | | | | | | | | | |
| | Flexural strength | 8 | 10 | 13 | 8 | 10 | 12 | 13 | 11 | 9 | 8 | 2 | 1 |
| | at 260° C., N/mm² | | | | | | | | | | | | |
| | Flexural modulus | 135 | 142 | 149 | 81 | 92 | 94 | 96 | 93 | 88 | 85 | 102 | 65 |
| | at 260° C., N/mm² | | | | | | | | | | | | |
| | Deflection | 7 | 6 | 5 | 13 | 12 | 10 | 10 | 10 | 9 | 8 | 1 | 1 |
| | at 260° C., mm | | | | | | | | | | | | |
| | Heat resistance | white | white | white | white | white | white | white | white | white | white | white | white |
| | or Yellowing | | | | | | | | | | | | |

Japanese Patent Application Nos. 2007-026659 and 2007-026508 are incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A thermosetting epoxy resin composition comprising
(A) a reaction product obtained through reaction of a triazine derived epoxy resin with an acid anhydride in an epoxy group equivalent to acid anhydride group equivalent ratio from 0.6 to 2.0,
(B) an internal parting agent,
(C) a reflective agent,
(D) an inorganic filler, and
(E) a curing catalyst,
said internal parting agent (B) comprising a component having the general formula (1) and a melting point in the range of 50° C. to 90° C., 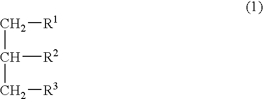
wherein R¹, R², and R³ are each independently H, —OH, —OR or —OCOCₐH_{b}, at least one of R¹, R², and R³ including —OCOCₐH_{b}, R is an alkyl group: CₙH₂ₙ₊₁ wherein n is an integer of 1 to 30, “a” is an integer of 10 to 30, and “b” is an integer of 17 to 61.

2. The composition of claim 1, further comprising (F) an antioxidant.

3. The composition of claim 1 wherein the triazine derived epoxy resin in component (A) is a 1,3,5-triazine nucleus derived epoxy resin.

4. The composition of claim 3 wherein the reaction product (A) comprises a compound having the general formula (2): 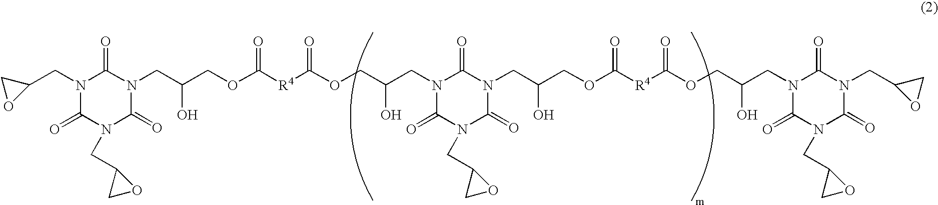
wherein R⁴ is an acid anhydride residue and m is a number from 0 to 200.

5. The composition of claim 1 wherein the internal parting agent (B) comprises glycerol monostearate having a melting point of 50 to 70° C. and is present in an amount of 0.2 to 5.0% by weight based on the total weight of the composition.

6. The composition of claim 1 wherein the internal parting agent (B) comprises a propylene glycol fatty acid ester and is present in an amount of 0.2 to 5.0% by weight based on the total weight of the composition.

7. The composition of claim 1 which is used to form a casing for semiconductor members excluding light-emitting members.

8. A thermosetting epoxy resin composition comprising
(A) a reaction product obtained through reaction of a triazine derived epoxy resin with an acid anhydride in an epoxy group equivalent to acid anhydride group equivalent ratio from 0.6 to 2.0,
(I) inorganic whisker fibers,
(C) a reflective agent,
(D) an inorganic filler, and
(E) a curing catalyst,
said whisker fibers (I) having an average fineness of 0.05 to 50 μm and an average length of 1.0 to 1,000 μm and being present in an amount of 0.001 to 30% by weight based on the total weight of the composition.

9. The composition of claim 8 further comprising (J) a silicone powder.

10. The composition of claim 9 wherein the silicone powder (J) is a powder of spherical silicone rubber particles surface coated with an epoxy resin.

11. The composition of claim 8 further comprising (F) an antioxidant.

12. The composition of claim 8 wherein the triazine derived epoxy resin in component (A) is a 1,3,5-triazine nucleus derived epoxy resin.

13. The composition of claim 12 wherein the reaction product (A) comprises a compound having the general formula (2): 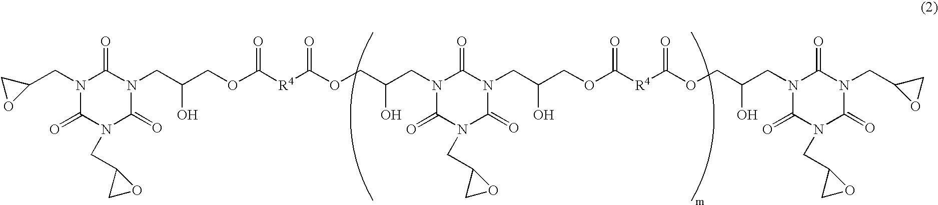
wherein R⁴ is an acid anhydride residue and m is a number from 0 to 200.

14. The composition of claim 8 which is used to form a casing for semiconductor members excluding light-emitting members.

15. A semiconductor device comprising a semiconductor member (exclusive of light-emitting members, but inclusive of integral members having light-emitting and receiving members combined), which is encapsulated with the epoxy resin composition of claim 1 in the cured state.

16. A semiconductor device comprising a semiconductor member (exclusive of light-emitting members, but inclusive of integral members having light-emitting and receiving members combined), which is encapsulated with the epoxy resin composition of claim 8 in the cured state.
